(19) United States
(12) Patent Application Publication
(10) Pub. No.: US 2011/0256690 A1
(43) Pub. Date: Oct. 20, 2011

(54) INTEGRATED CIRCUIT WAFER DICING METHOD

(76) Inventor: Yao-Sheng Huang, Kaohsiung City (TW)

(21) Appl. No.: 13/089,472

(22) Filed: Apr. 19, 2011

(30) Foreign Application Priority Data
Apr. 20, 2010 (TW) 099112292

(51) Int. Cl. H01L 21/78

(52) U.S. Cl. 438/464; 257/E21.599

(57) ABSTRACT

An integrated circuit wafer dicing method is provided. The method includes forming a plurality of integrated circuits on a wafer substrate, forming a patterned protective layer on the integrated circuits, and etching through the wafer substrate to form a plurality of integrated circuit dies by using the patterned protective layer as a mask. The patterned protective layer is preferably a patterned photoresist layer. The step of forming the patterned protective layer includes covering the wafer substrate with a photoresist layer, exposing the photoresist layer by using a photomask, and developing the exposed photoresist layer to form the patterned protective layer. The etching process can be dry etching or wet etching.

### CROSS-REFERENCE TO RELATED APPLICATION

This application claims priority based on Taiwanese Patent Application No. 099112292, filed on Apr. 20, 2010, the disclosure of which is incorporated herein by reference in its entirety.

### BACKGROUND OF THE INVENTION

1. Field of the Invention

This invention generally relates to an integrated circuit wafer dicing method, wherein a plurality of integrated circuit dies are formed from an integrated circuit wafer by the integrated circuit wafer dicing method.

2. Description of the Prior Art

A wafer is a substrate for manufacturing integrated circuits. Using integrated circuit fabrication technology, through a series of complicated chemical, physical, and optical processes, a fabricated integrated circuit wafer can include thousands or hundreds of integrated circuit dies. After being tested, cut, and packaged, these dies can be formed into various integrated circuit products having different functions.

FIG. 1A shows a conventional integrated circuit wafer 90 and an enlarge view of the area 80; FIG. 1B shows a cross-sectional view of the area 80 of FIG. 1A indicated by PP. As shown in FIGS. 1A and 1B, the conventional integrated circuit wafer 90 includes a wafer substrate 100, a plurality of integrated circuits 300, a plurality of test-keys 400, and a protecting layer 500. In a conventional wafer dicing process, an external force K is applied by a cutter to the integrated circuit wafer 90 along a path between two adjacent integrated circuits 300. Because the cutter is directly applied onto the integrated circuit wafer 90, cracks and damages of the integrated circuit wafer 90 will be produced due to the dicing stress. Therefore, it is desired to improve the conventional dicing method.

### SUMMARY

It is an object of the present invention to provide an integrated circuit wafer which can be separated into multiple integrated circuit dies with improved yield rate.

The method includes forming a plurality of integrated circuits on a wafer substrate, forming a patterned protective layer on the integrated circuits, and etching through the wafer substrate to form a plurality of integrated circuit dies by using the patterned protective layer as a mask. The patterned protective layer is preferably a patterned photoresist layer.

The step of forming the patterned protective layer includes covering the wafer substrate with a photoresist layer, exposing the photoresist layer by using a photomask, and developing the exposed photoresist layer to form the patterned protective layer. The etching process can be dry etching or wet etching.

The method further includes attaching the wafer substrate to a support body from a side opposite to the integrated circuits before the step of etching. The method further includes separating the plurality of integrated circuit dies from the support body after the step of etching. The method further includes forming an isolation layer to cover the integrated circuits on the wafer substrate before the step of forming the patterned protective layer.

### BRIEF DESCRIPTION OF THE DRAWINGS

FIGS. 1A and 1B are schematic views of the prior art;

FIG. 2 is a flowchart of the integrated circuit wafer dicing method of the present invention;

FIGS. 3A and 3B are schematic views of forming a plurality of integrated circuits on a wafer substrate in an embodiment of the present invention;

FIGS. 4A to 4B are schematic views of forming a patterned protective layer in an embodiment of the present invention;

FIGS. 5A and 5B are schematic views of an embodiment of the present invention having a patterned protective layer;

FIG. 6 is a schematic view of an integrated circuit die formed in an embodiment of the present invention;

FIG. 7 is a flowchart of another embodiment of the present invention;

FIGS. 8A and 8B are schematic views of an embodiment of the present invention showing that the side of the wafer substrate opposite to the integrated circuits is attached to a support body;

FIG. 9 is a flowchart of a preferred embodiment of the present invention;

FIG. 10 is a schematic view of an embodiment of the present invention showing an isolation layer covering the wafer substrate;

FIG. 11A is a schematic view of a preferred embodiment of the present invention showing a patterned protective layer formed on the integrated circuits; and

FIG. 11B is a schematic view of an integrated circuit die formed in a preferred embodiment of the present invention;

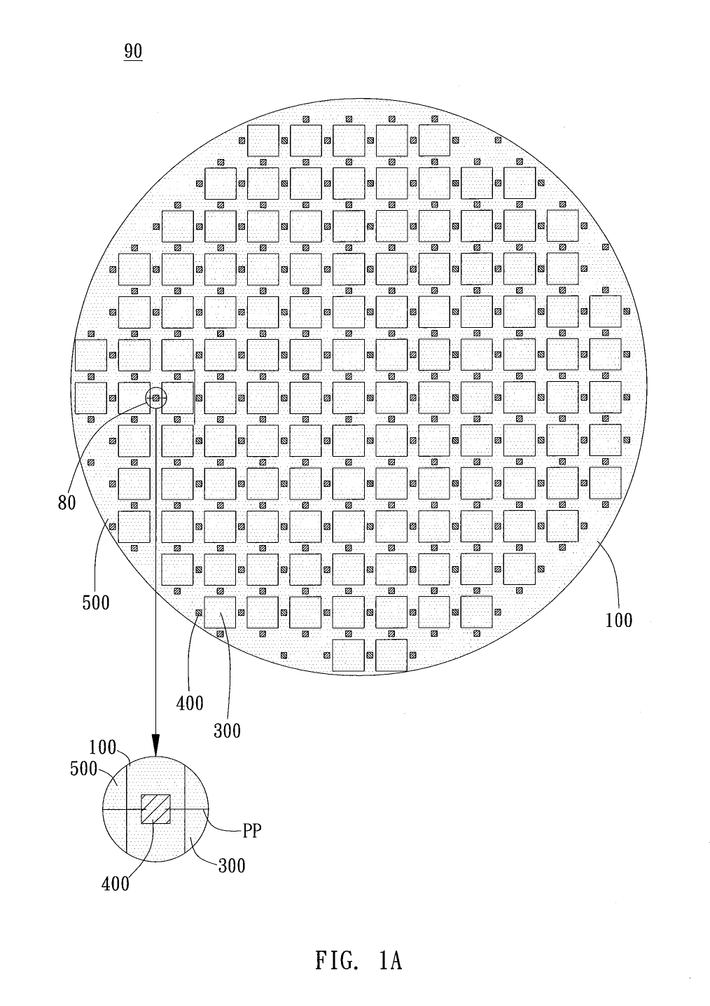

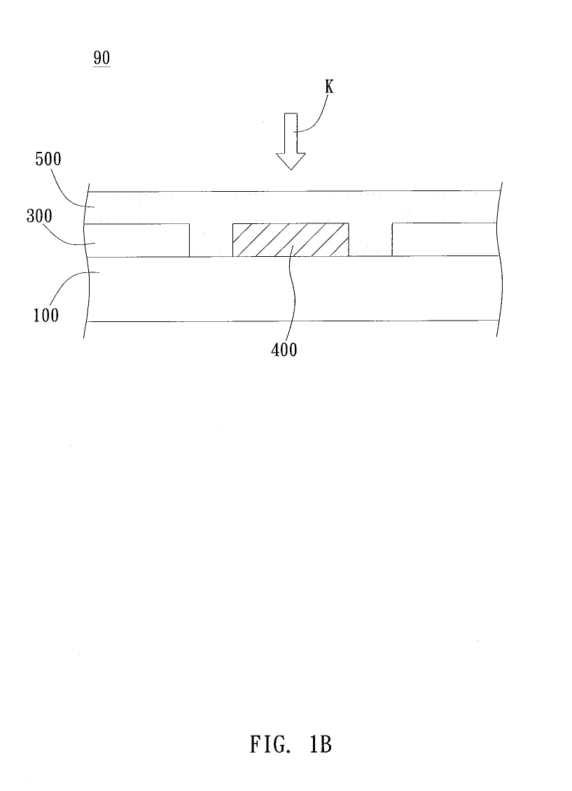

### DETAILED DESCRIPTION OF THE PREFERRED EMBODIMENT

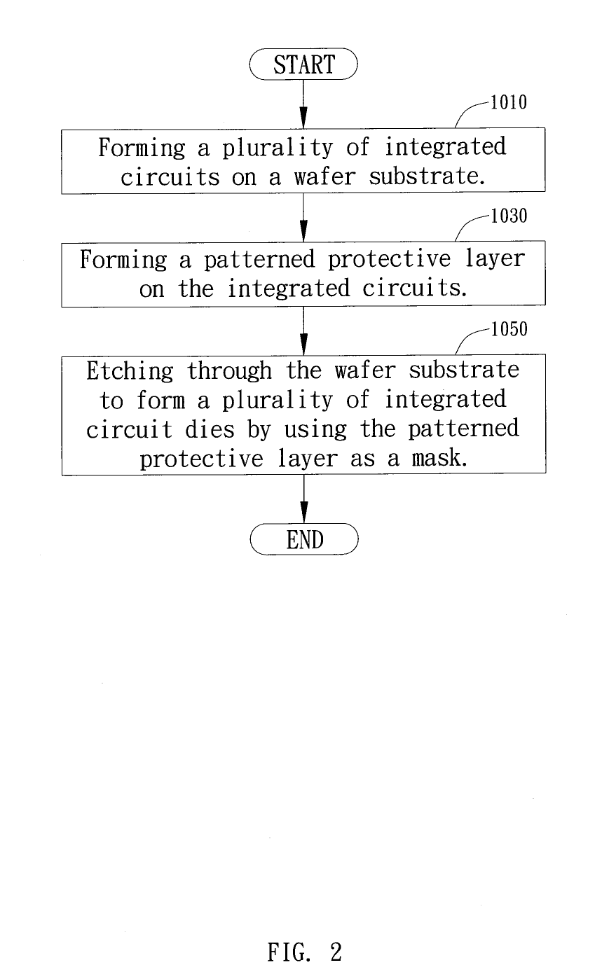

As shown in FIG. 2, the integrated circuit wafer dicing method of the present invention includes the following steps.

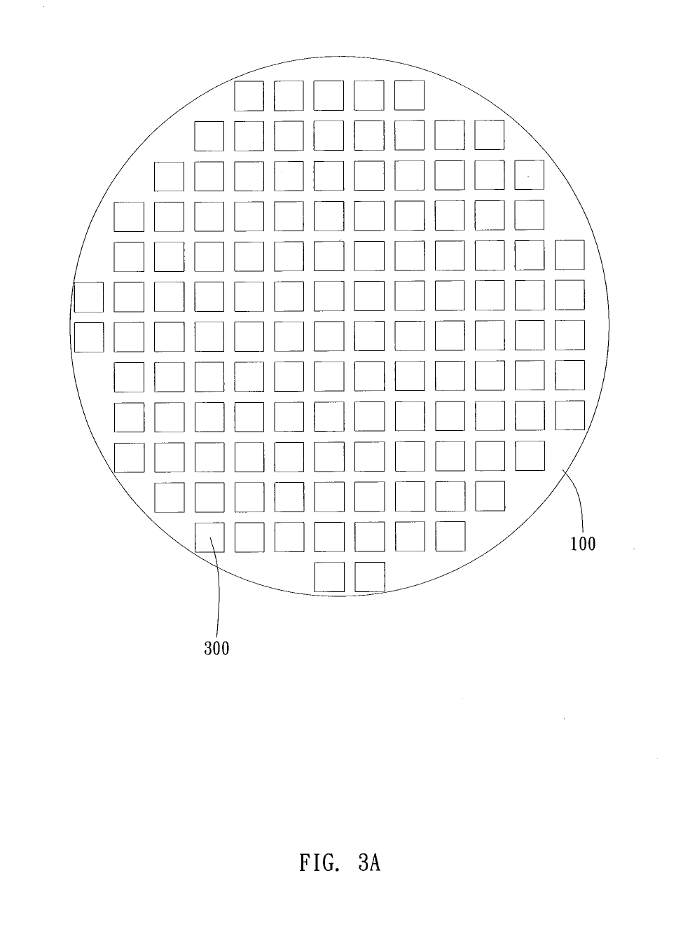

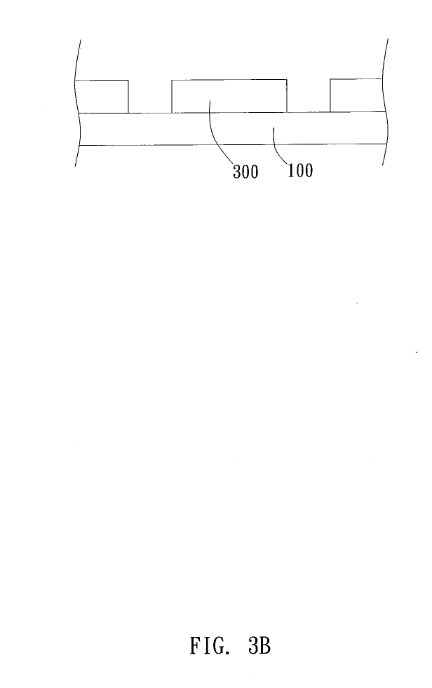

Step 1010, the step of forming a plurality of integrated circuits on a wafer substrate is performed. More particularly, as shown in FIGS. 3A and 3B, the integrated circuits 300 are formed on the wafer substrate 100 by semiconductor processing steps such as deposition, photolithography, etching, thermal processes, etc.

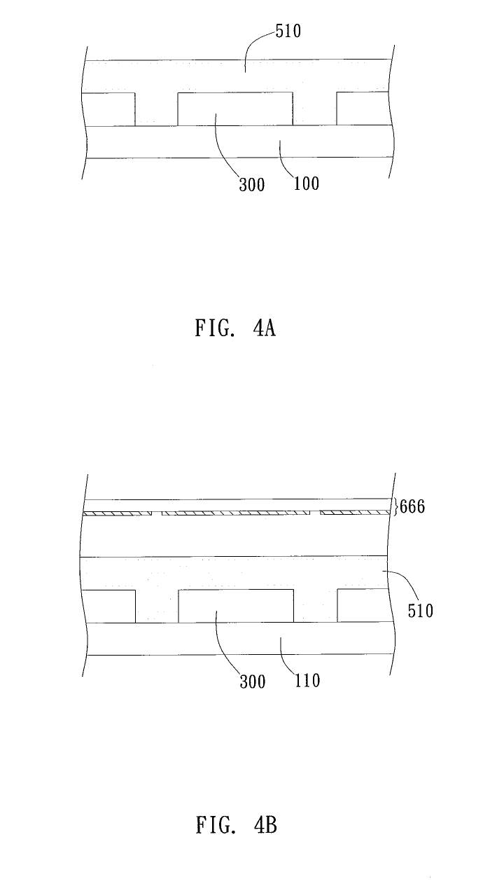

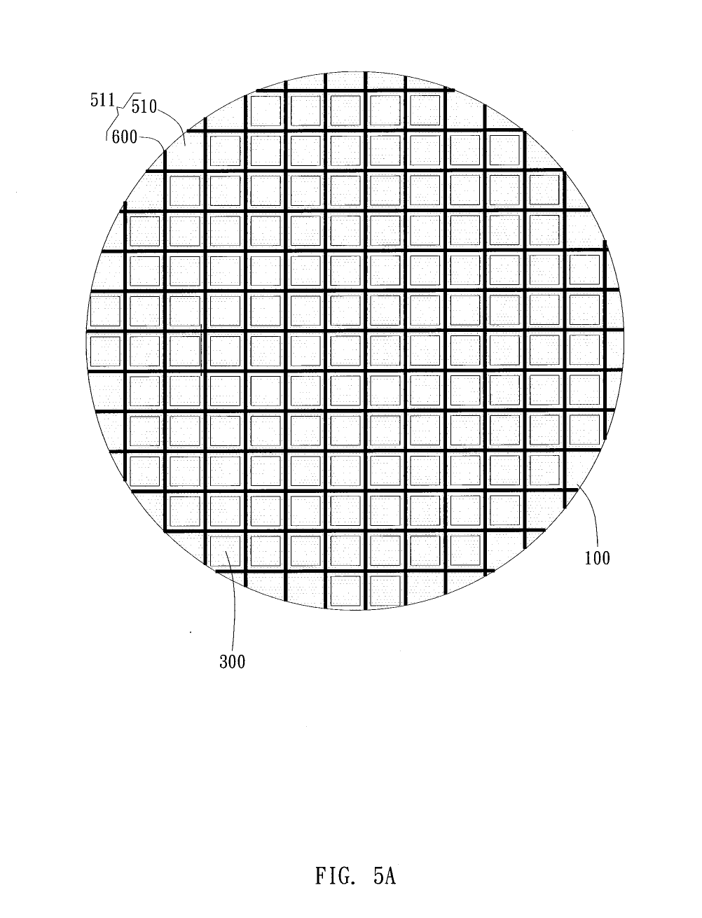

Step 1030, the step of forming a patterned protective layer on the integrated circuits is performed, wherein the patterned protective layer is preferably a patterned photoresist layer. More particularly, the step of forming the patterned protective layer includes covering the wafer substrate 100 with a photoresist layer 510 as shown in FIG. 4A, exposing the photoresist layer 510 by using a photomask 666 as shown in FIG. 4B, and developing the exposed photoresist layer 510 to form the patterned protective layer 511 as shown in FIGS. 5A and 5B. The photoresist layer 510 shown in FIG. 4A is preferably a blanket layer covering the wafer substrate 100 and the integrated circuits 300 thereon by spin coating. The patterned protective layer 511 shown in FIGS. 5A and 5B is an exposed and developed photoresist layer having a plurality of ditches 600. The ditches 600 extend downwardly from the surface (i.e. upper surface) of the patterned protective layer 511 and are disposed between the integrated circuits 300. The patterned protective layer 511 covers the integrated circuits 300.

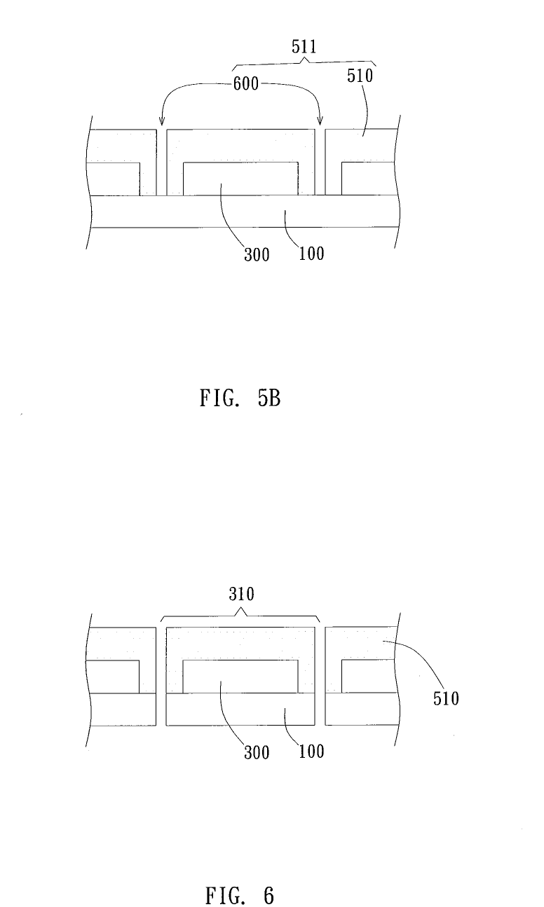

Step 1050, the step of etching through the wafer substrate to form a plurality of integrated circuit dies by using the patterned protective layer as a mask is performed. More particularly, the wafer substrate 100 shown in FIG. 6 is etched through by a dry plasma etching process or a wet chemical etching process to form a plurality of separated integrated circuit dies 310.

By performing the above mentioned steps in the method of the present invention, a plurality of separated integrated circuit dies 310 can be formed without using a cutting tool. Therefore, cracks and damages of the integrated circuit wafer caused by the dicing stress can be prevented. Moreover, when the plurality of integrated circuits 300 are formed on the wafer substrate in step 1010, the intervals between the adjacent integrated circuits 300 can be reduced to increase the density of integrated circuit dies 310 per unit area since the separation is substantially done by etching. Furthermore, for the convenience of dicing, the integrated circuit dies in prior arts are often in same size and disposed in matrix, yet there is no such limitation for the present invention.

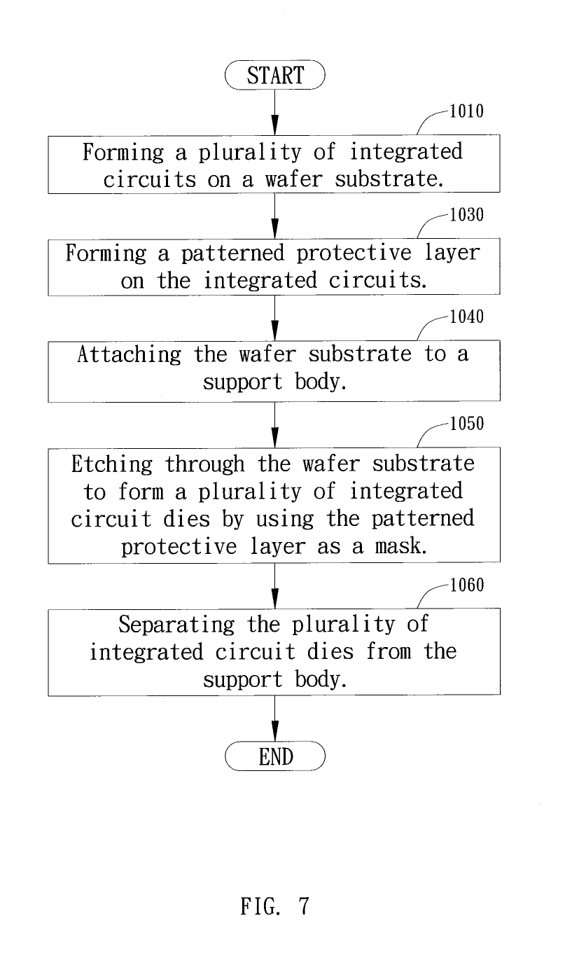

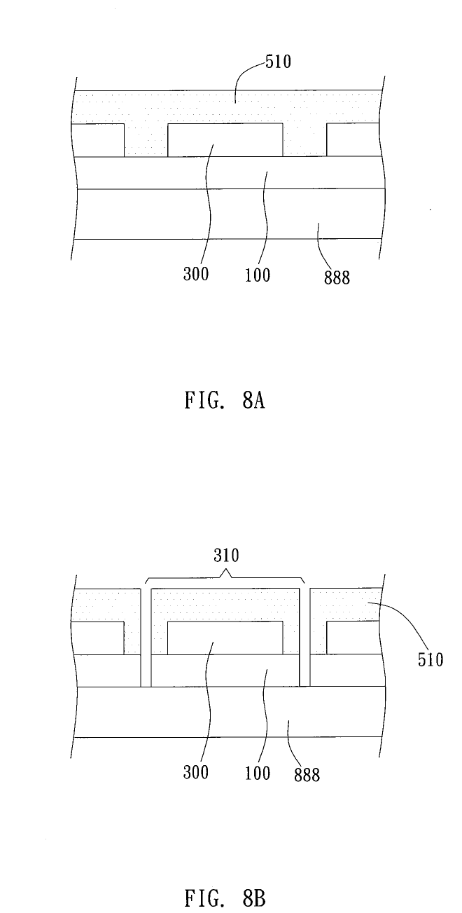

In another embodiment shown in FIG. 7, for the convenience of processing, the integrated circuit wafer dicing method of the present invention further includes the following steps. Step 1040, the step of attaching the wafer substrate 100 to a support body 888 before step 1050 is performed. As shown in FIG. 8A, the wafer substrate 100 is attached to the support body 888 from the side that is opposite to the integrated circuits 300. That is, if the integrated circuits 300 are formed on the front side of the wafer substrate 100, then it is the rear side of the wafer substrate 100 to be attached to the support body 888. Step 1060, the step of separating the plurality of integrated circuit dies 310 from the support body 888 after step 1050 is performed. More particularly, especially for the case that step 1050 is wet etching, it is difficult to collect the separated integrated circuit dies 310 since they are scattered in the etching solution after the wafer substrate 100 is etched through. By attaching the side of the wafer substrate 100 opposite to the integrated circuits 300 to the support body 888 before etching, the individual integrated circuit die 310 after the wafer substrate 100 is etched through will be attached to and stay on the surface of the support body 888 as shown in FIG. 8B, instead of scattering in the etching solution. The support body 888 is preferably a tape. In different embodiments, however, the support body 888 can be an object resistible to the corrosion of the etching solution.

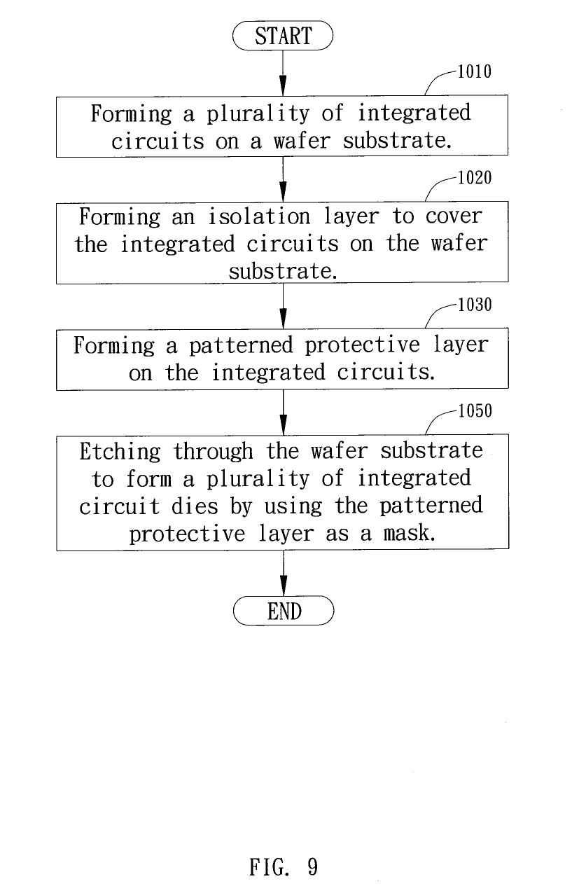

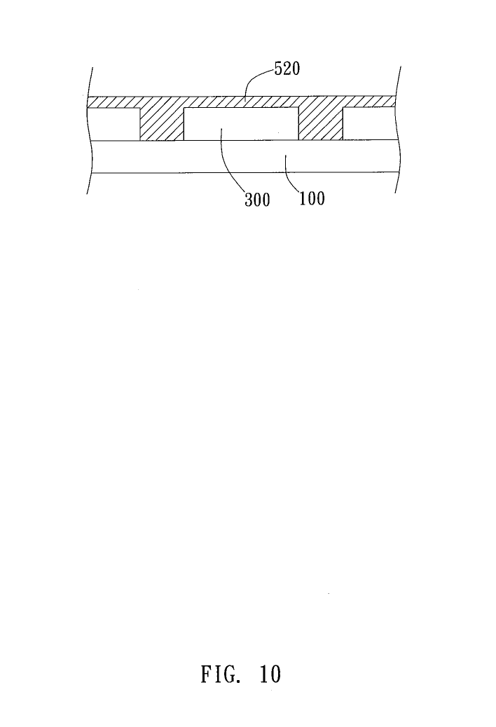

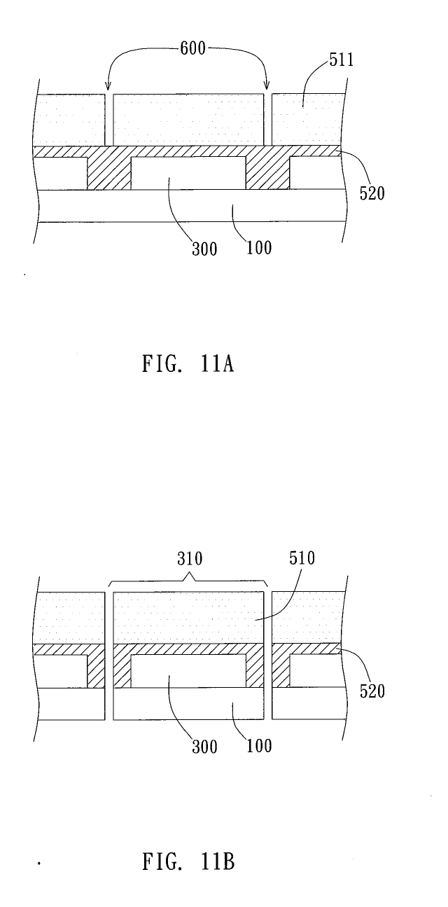

In a preferred embodiment shown in FIG. 9, the integrated circuit wafer dicing method further includes step 1020, a step of forming an isolation layer to cover the integrated circuits on the wafer substrate before step 1030 is performed. More particularly, as shown in FIG. 10, the isolation layer 520 is a blanket layer covering the wafer substrate 100 and the integrated circuits 300 thereon. In other words, in the preferred embodiment, the patterned protective layer 511 will be formed on the isolation layer 520 and cover the underlying integrated circuits 300 as shown in FIG. 11A, wherein the integrated circuit die 311 shown in 11B will be formed after step 1050.

Although the preferred embodiments of the present invention have been described herein, the above description is merely illustrative. Further modification of the invention herein disclosed will occur to those skilled in the respective arts and all such modifications are deemed to be within the scope of the invention as defined by the appended claims.

What is claimed is:

1. An integrated circuit wafer dicing method, comprising:
forming a plurality of integrated circuits on a wafer substrate;
forming a patterned protective layer on the integrated circuits; and
etching through the wafer substrate to form a plurality of integrated circuit dies by using the patterned protective layer as a mask.

2. The integrated circuit wafer dicing method of claim 1, wherein the patterned protective layer is a patterned photoresist layer.

3. The integrated circuit wafer dicing method of claim 1, wherein the step of forming the patterned protective layer includes:
covering the wafer substrate with a photoresist layer;
exposing the photoresist layer by using a photomask; and
developing the exposed photoresist layer to form the patterned protective layer.

4. The integrated circuit wafer dicing method of claim 1, wherein the step of etching is dry etching.

5. The integrated circuit wafer dicing method of claim 1, wherein the step of etching is wet etching.

6. The integrated circuit wafer dicing method of claim 5, further comprising attaching the wafer substrate to a support body before the step of etching.

7. The integrated circuit wafer dicing method of claim 6, further comprising separating the plurality of integrated circuit dies from the support body after the step of etching.

8. The integrated circuit wafer dicing method of claim 1, further comprising forming an isolation layer to cover the integrated circuits on the wafer substrate before the step of forming the patterned protective layer.
